(19) United States
(12) Patent Application Publication
(10) Pub. No.: US 2007/0158799 A1
(43) Pub. Date: Jul. 12, 2007

(54) Interconnected IC packages with vertical SMT pads

(76) Inventors: Chin-Tien Chiu, Taichung City (TW); Cheemen Yu, Madison, WI (US); Hem Takiar, Fremont, CA (US); Jack Chang Chien, Kaoshiung City (TW); Meng-Ju Tsai, Kaohsiung (TW)

Correspondence Address: VIERRA MAGEN/SANDISK CORPORATION, 575 MARKET STREET, SUITE 2500, SAN FRANCISCO, CA, 94105, US

(21) Appl. No.: 11/322,017

(22) Filed: Dec. 29, 2005

(51) Int. Cl. H01L 23/02

(52) U.S. Cl. 257/678

(57) ABSTRACT

An electronic component is disclosed including a plurality of semiconductor packages soldered together in a side-by-side configuration. The packages are batch processed on a substrate panel. The panel includes a plurality of through-holes drilled through the panel and subsequently filled with metal such as copper or gold. These filled through-holes lie along the cut line between adjacent packages so that, upon singulation, the filled through holes are cut and a portion of the filled through-holes are exposed at the side edges of the singulated packages. These exposed portions of the filled through-holes form vertical surface mount technology (SMT) pads. After the semiconductor packages are singulated and the SMT pads are defined in the side edges, SMT is used to solder the SMT pads of a first semiconductor package to the respective SMT pads of a second semiconductor package to structurally and electrically couple the two packages together side-by-side.

### BACKGROUND OF THE INVENTION

1. Field of the Invention

Embodiments of the present invention relate to an electronic component formed of a plurality of coupled semiconductor packages, and a method of forming the electronic component.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid base having a conductive layer etched on one or both sides. Electrical connections are formed between the die and the conductive layer(s), and the conductive layer(s) provide an electric lead structure for integration of the die into an electronic system. Once electrical connections between the die and substrate are made, the assembly is then typically encased in a molding compound to provide a protective package.

In view of the small form factor requirements, as well as the fact that flash memory cards need to be removable and not permanently attached to a printed circuit board, such cards are often built of a land grid array (LGA) package. In an LGA package, the semiconductor die are electrically connected to exposed contact fingers formed on a lower surface of the package. External electrical connection with other electronic components on a host printed circuit board (PCB) is accomplished by bringing the contact fingers into pressure contact with complementary electrical pads on the PCB. LGA packages are ideal for flash memory cards in that they have a smaller profile and lower inductance than pin grid array (PGA) and ball grid array (BGA) packages.

A cross-section of a conventional LGA package 40 is shown in FIG. 1. One or more die 20 are mounted on a substrate 22 in a stacked configuration via die attach 24. The dice are shown separated by a dielectric spacer layer 26. In embodiments, the die 22 may be affixed to dielectric spacer layer 26 by an epoxy. Generally, the substrate 22 is formed of a rigid core 28, of for example BT (Bismaleimide Triazine) laminate. Thin film copper layer(s) 30 may be formed on the core in a desired electrical lead pattern, including exposed surfaces for the contact fingers, using known photolithography and etching processes. The contact fingers 32 may be formed of a layer of gold deposited on the copper layer 30 to provide the electrical connection of the package to the host PCB.

The substrate may be coated with a solder mask 36, leaving the contact fingers 32 exposed, to insulate and protect the electrical lead pattern formed on the substrate. The solder mask covers the surfaces of the substrate, leaving the contact fingers 32 exposed. The die may be electrically connected to the substrate by wire bonds 34. Vias (not shown) are formed through the substrate to allow electrical connection of the die through the substrate to the contact fingers 32. Once the dice are electrically connected, the package may be encapsulated in a molding compound 38 to form the package 40. Further examples of typical LGA packages are disclosed in U.S. Pat. Nos. 4,684,184, 5,199,889 and 5,232,372, which patents are incorporated by reference herein in their entirety.

There is an ever-present drive to increase storage capacity while at the same time maintaining or even decreasing the package form factor, and in particular the height of the semiconductor package. In typical packages, the thickness of the encapsulated package may for example be approximately 0.65 mm, though this height may vary. Recent advances in packaging technology have resulted in reduction of the footprint (i.e., the length and width) of semiconductor packages. In particular, where memory cards in the past have included several individually packaged integrated circuits mounted on a printed circuit board, SiP and MCM packages have a much smaller footprint. Thus, while it may not be allowable or desirable to increase the height of a semiconductor package, advances in packaging technology have freed up footprint space on memory cards.

### SUMMARY OF THE INVENTION

Embodiments of the invention, roughly described, relate to an electronic component including a plurality of semiconductor packages soldered together in a side-by-side configuration. The packages are batch processed on a substrate panel. The panel includes a plurality of through-holes drilled through the panel and subsequently filled with metal such as copper or gold. These filled through-holes lie along the cut line between adjacent packages so that, upon singulation, the filled through holes are cut and a portion of the filled through-holes are exposed at the side edges of the singulated packages. These exposed portions of the filled through-holes form vertical surface mount technology (SMT) pads. After the semiconductor packages are singulated and the SMT pads are defined in the side edges, SMT is used to solder the SMT pads of a first semiconductor package to the respective SMT pads of a second semiconductor package to structurally and electrically couple the two packages together side-by-side.

The conductance pattern(s) in a given semiconductor package are coupled to some or all of the SMT pads in that package. The conductance pattern(s) in semiconductor packages to be coupled are also configured such that, once the packages are coupled together via the SMT pads, the semiconductor die in one package are electrically coupled to the semiconductor die and/or contact fingers in the second package. Thus, once soldered together, the semiconductor packages may function as a single electronic component, such as for example a single flash memory device. The semiconductor packages which are coupled together may originate from the same panel, or from different panels.

After the electronic component is formed, it may be encased in an industry standard lid enclosure to form any of various known standard flash memory format devices, including a Secure Digital (SD) card, a Compact Flash, a Smart Media, a Mini SD Card, an MMC, an xD Card, a Transflash memory card or a Memory Stick.

### DESCRIPTION OF THE DRAWINGS

FIG. 1 is a cross sectional end view of a conventional semiconductor package including semiconductor die mounted on a substrate.

FIG. 2 is a cross sectional side view of a portion of a substrate panel including semiconductor die, molding compound and a filled through-hole according to embodiments of the present invention.

FIG. 3 is a top view of a portion of a substrate panel including a pair of semiconductor packages prior to singulation.

FIG. 4 is a perspective view of a semiconductor package including conductive SMT pads on an edge of the package according to embodiments of the present invention.

FIG. 5 is a flowchart of a process for forming substrates according to embodiments of the present invention.

FIG. 6 is a side view of a pair of semiconductor packages soldered side-by-side according to embodiments of the present invention.

FIG. 7 is a top view of a pair of semiconductor packages soldered side-by-side according to embodiments of the present invention.

FIG. 8 is a top view of a pair of semiconductor packages soldered side-by-side and encased within a lid according to embodiments of the present invention.

FIGS. 9 through 13 are alternative embodiments of an electronic component according to the present invention.

FIG. 14 is a flowchart of a process for forming a semiconductor package according to embodiments of the present invention.

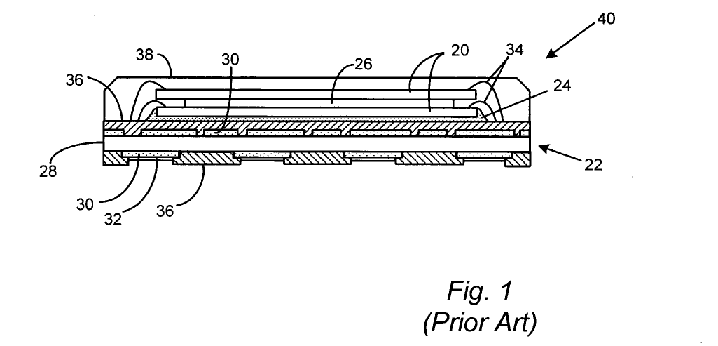

### DETAILED DESCRIPTION

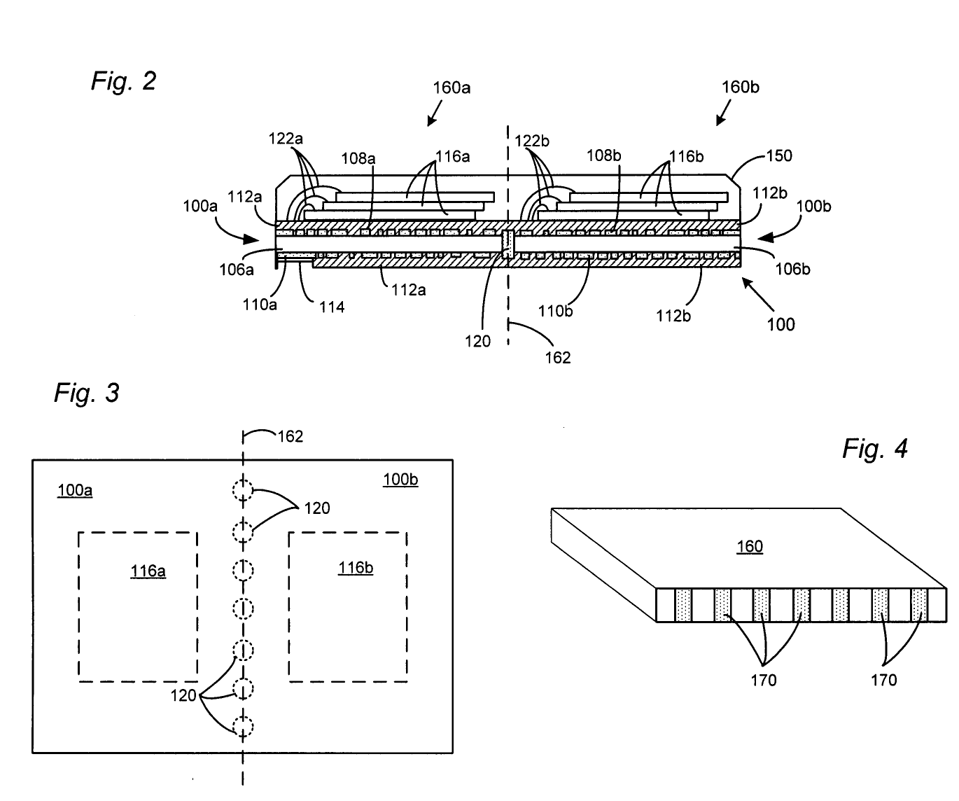

Embodiments will now be described with reference to FIGS. 2 through 14, which roughly described, relate to side-by-side soldered semiconductor packages. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

FIG. 2 is a cross-sectional side view of two semiconductor devices fabricated together on a substrate panel 100. The substrate panel 100 includes substrates 100a and 100b, which substrates will form parts of the respective semiconductor packages upon singulation of the packages from the substrate panel as explained hereinafter. Panel 100 may include an array of any desired number of pairs of substrates 100a and 100b. Alternatively, the panel 100 may include an n×m array of substrates 100, where n and m are selected as desired. Substrate panel 100 may be a variety of different chip carrier mediums, including a PCB, a leadframe or a tape automated bonded (TAB) tape. The following is a description of the components of substrate 100a. It is understood that the same description applies to the components of substrate 100b except where noted.

Where substrate panel 100 is PCB, the substrate 100a may be formed of a core 106a, having a top conductive layer 108a formed on the top surface of the core 106a, and a bottom conductive layer 110a formed on the bottom surface of the core. The core 106a may be formed of various dielectric materials such as for example, polyimide laminates, epoxy resins including FR4 and FR5, bismaleimide triazine (BT), and the like. Although not critical to the present invention, core 106a may have a thickness of between 40 microns (μm) to 200 μm, although the thickness of the core may vary outside of that range in alternative embodiments. The core 106a may be ceramic or organic in alternative embodiments.

The conductive layers 108a and 110a may be formed of copper or copper alloys, plated copper or plated copper alloys, Alloy 42 (42Fe/58Ni), copper plated steel, or other metals and materials known for use on substrate panels. The layers 108a and 110a may have a thickness of about 10 μm to 24 μm, although the thickness of the layers 108a and 110a may vary outside of that range in alternative embodiments.

In accordance with embodiments of the present invention, substrate panel 100 may further include filled through-holes 120 as seen in FIGS. 2 and 3. The filled through-holes 120 will form vertical surface mount technology (SMT) conductive pads in the edges of the substrates 100a and 100b upon singulation as explained hereinafter. As is further explained hereinafter, the SMT pads are used solder together semiconductor packages using either solder paste or solder balls.

Referring to FIG. 3, the holes 120 may be formed in substrate panel by drilling through the substrate panel at a variety of pitches (i.e., spacing of the holes from each other). In embodiments using solder paste, the pitch may for example be approximately 0.8 mm and higher. In embodiments using solder balls, the pitch may for example be approximately 0.5 mm and higher. It is understood that the pitch between adjacent through-holes 120 may be smaller than 0.8 mm for solder paste, and smaller than 0.5 mm for solder balls in alternative embodiments. In embodiments, the size of the through-holes 120 in solder paste and solder ball embodiments may be approximately 0.5 mm and 0.2 mm, respectively, or larger. It is understood that the size of the through-holes 120 in solder paste and solder ball embodiments may be smaller than 0.5 mm and 0.2 mm, respectively, in alternative embodiments.

Thus, an embodiment where the through-holes 120 were formed in an edge that is 15 mm long could for example have 18 through-holes 120. An embodiment where the through-holes 120 were formed in an edge that is 18 mm long could for example have 22 through-holes 120. And an embodiment where the through-holes 120 were formed in an edge that is 22 mm long could for example have 26 through-holes 120.

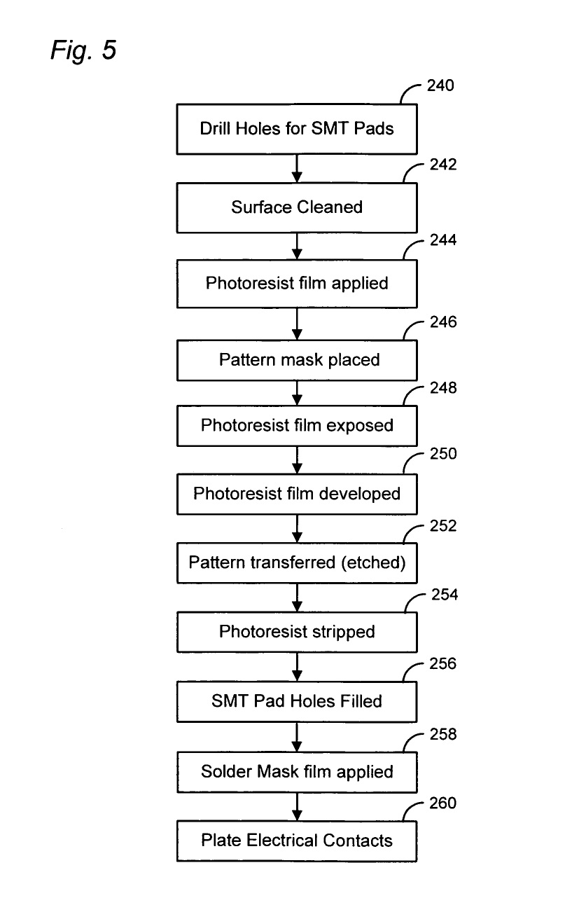

The layer 108a and/or layer 110a may be etched with a conductance pattern for communicating signals between one or more semiconductor die and an external device. The conductance pattern in layer 108a and/or layer 110a may also be coupled to filled through-holes 120 to allow electrical signals and current flow between soldered side-by-side semiconductor packages as explained hereinafter. One process for forming the substrate panel 100 including the conductance pattern on the upper and/or lower surfaces of substrate panel 100 is explained with reference to the flowchart of FIG. 5. The holes 120 are first drilled in step 240 as explained above. The surfaces of conductive layers 108a and 110a are cleaned in step 242. A photoresist film is then applied over the surfaces of layers 108a and 110a in step 244. A pattern mask containing the outline of the electrical conductance pattern may then be placed over the photoresist film in step 246. The photoresist film is exposed (step 248) and developed (step 250) to remove the photoresist from areas on the conductive layers that are to be etched. The exposed areas are next etched away using an etchant such as ferric chloride in step 252 to define the conductance patterns on the core. Next, the photoresist is removed in step 254. Other known methods for forming the conductance pattern on substrate panel 100 are contemplated.

Once the conductance pattern in formed, the through-holes 120 may be plated and filled in a step 256. In embodiments, the through-holes 120 may first be plated in a known through-hole plating process with a metal such a for example copper, copper alloys, Alloy 42 (42Fe/58Ni), copper plated steel, gold, silver or other metals and materials. Thereafter, the plated through-holes 120 may be filled with a metal such as for example copper, copper alloys, Alloy 42, gold, silver or other metals and materials.

Thereafter, the top and bottom conductive layers 108a, 110a may be laminated with a solder mask 112a in a step 258. In embodiments where substrate panel 100 is used for example as an LGA package, one or more gold layers may be formed on portions of the bottom conductive layer 110a in step 260 to define contact fingers 114 as is known in the art for communication with external devices. In embodiments, only one of the semiconductor packages formed of substrates 100a and 100b will directly couple with a host device via the contact fingers 114. Thus, only one of the substrates 100a, 100b may be formed with contact fingers 114. It is understood that contact fingers 114 may be formed in both substrates 100a and 100b in alternative embodiments. The one or more plated layers may be applied in a known electroplating process. It is understood that the present invention may be used with other types of semiconductor packages, including for example BGA packages.

After the substrate 100a is formed, semiconductor die 116a may be mounted to the surface of the substrate 100a. FIG. 2 shows three offset stacked semiconductor die 116a mounted on the substrate panel 100. Alternatively, the die 116a could be stacked in an aligned configuration and be separated by a silicon spacer as is known in the art. The offset allows electrical leads to be connected to each of the semiconductor die in the stack, at the edges of the die. Embodiments of the invention may alternatively include 1 or 2 die 116a, and embodiments of the invention may alternatively include between 4 and 8 or more die 116a stacked in an SiP, MCM or other type of arrangement. The one or more die may have thicknesses ranging between 2 mils to 20 mils, but the one or more die 116a may be thinner than 2 mils and thicker than 20 mils in alternative embodiments. The one or more die 116a may be a flash memory chip (NOR/NAND), SRAM or DDT, and/or a controller chip such as an ASIC. Other silicon chips are contemplated. As explained in greater detail below, the substrate 100a may have the same semiconductor die as substrate 100b, or the substrate 100a may have different semiconductor die than the substrate 100b.

The one or more die 116a may be mounted on the top surface of the substrate panel 100 using a known adhesive or eutectic die bond process, with a known die attach compound. The one or more die 116a in FIG. 2 may be electrically connected to conductive layers 108a, 110a of the substrate 100a by wire bonds 122a using a known wire bond process.

Once the die are mounted and connected, the entire substrate panel 100 including die 116a and 116b may be encased within a molding compound 150 in a known encapsulation process to form finished semiconductor die packages 160a, 160b. Molding compound 150 may be an epoxy such as for example available from Sumitomo Corp. and Nitto Denko Corp., both having headquarters in Japan. Other molding compounds from other manufacturers are contemplated. The molding compound may be applied according to various processes, including by transfer molding or injection molding techniques, to encapsulate the substrate panel 100 and semiconductor die 116a and 116b.

After the panel 100 is encapsulated, the panel may be cut to singulate the respective semiconductor packages 160a, 160b from the panel. Each semiconductor package 160a, 160b may be singulated by sawing along straight cut line 162 (shown in phantom in FIGS. 2 and 3). The cuts may have a kerf of approximately, 0.3 mm, but the kerf may be narrower or wider than that in alternative embodiments. Instead of sawing, the packages 160a, 160b the panel 100 may be singulated by a variety of cutting methods in alternative embodiments, such as for example, water jet cutting, laser cutting, water guided laser cutting, dry media cutting, and diamond coated wire. Water can also be used together with laser cutting to help complement or focus its effects. A further description of the cutting of integrated circuits from a panel and the shapes which may be achieved thereby is disclosed in published U.S. Application No. 2004/0259291, entitled, “Method For Efficiently Producing Removable Peripheral Cards,” which application is assigned to the owner of the present invention and which application has been incorporated by reference herein in its entirety. It is understood that the singulated packages 160a, 160b may be formed by other processes than that described above in alternative embodiments.

Once cut into packages 160a, 160b, the packages may be separately tested to determine whether the packages are functioning properly. As is known in the art, such testing may include electrical testing, burn in and other tests.

FIG. 4 shows a semiconductor package 160, which may be either of the packages 160a or 160b described above. The filled through-holes 120 lie along the cut line 162 between adjacent packages 160a and 160b. When the packages are singulated, the filled through-holes are bisected, resulting in portions of the filled through-holes being exposed along a side edge of the packages 160a and 160b. As seen in FIG. 4, these exposed portions of the filled through-holes define vertical SMT pads 170 which are used for soldering the packages 160a and 160b to each other, and/or to other packages similarly formed as described above to include vertical SMT pads 170.

In embodiments, the semiconductor packages 160a, 160b may be singulated into square or rectangular shapes. However, in alternative embodiments, the packages 160a, 160b may have one or more curvilinear or irregular shaped edges, and the SMT pads 170 may be positioned along one or more of these curvilinear or irregular shaped edges.

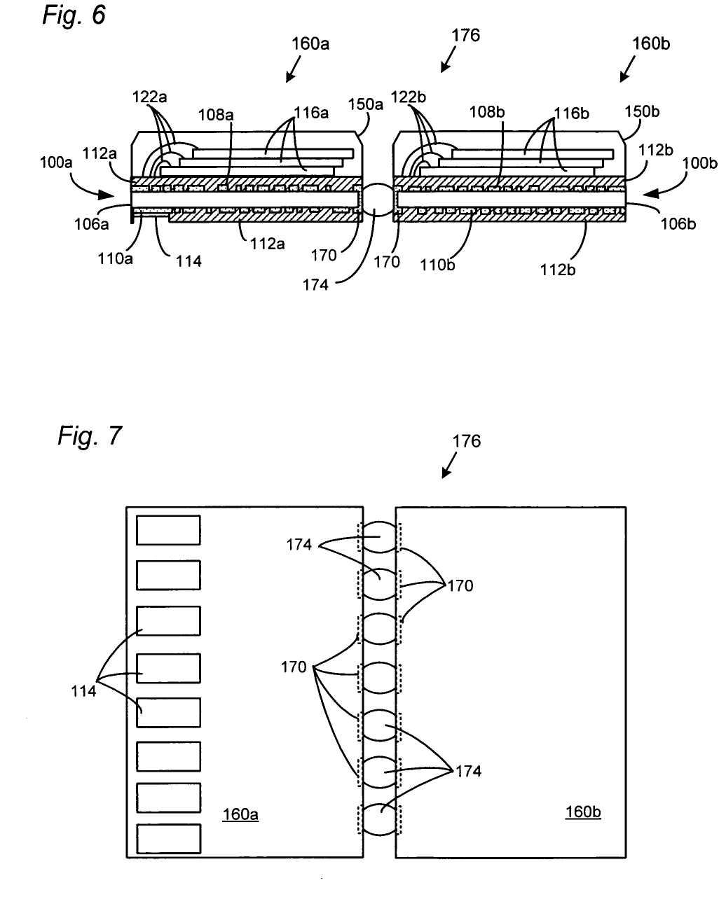

Referring now to FIGS. 6 and 7, once packages 160a and 160b are singulated and SMT pads 170 are defined, the packages 160a and 160b may be soldered together, or to other packages having SMT pads 170, in an SMT process. SMT is generally known as a method of soldering components to plated portions of a substrate. In embodiments of the present invention, SMT is used to solder SMT pads 170 of a first semiconductor package to the respective SMT pads of a second semiconductor package to electrically couple the two packages together side-by-side.

Referring to FIGS. 6 and 7, a solder paste 174 may be applied between the SMT pads 170 of packages 160a and 160b to be joined in a solder printing process. After solder paste 174 is applied, the packages may be heated in a reflow process to remove flux from the solder paste 174 and harden the solder to electrically couple and structurally bond the respective packages 160a and 16b together.

As an alternative to solder paste applied in a solder printing process, it is understood that solder balls of known construction may be used in a solder ball placement process to couple respective SMT pads on adjoining packages. The packages and solder balls may then be heated in a known reflow process. It is further contemplated that other electrically conductive materials may be used instead of solder paste or solder balls to electrically and structurally couple packages 160a and 160b together in alternative embodiments.

As would be appreciated by those of skill in the art, the conductance pattern(s) in a given semiconductor package are coupled to some or all of the SMT pads 170 in that package. The conductance pattern(s) in the respective semiconductor packages are also configured in a known manner such that, once the packages are coupled together via the SMT pads, the semiconductor die in one package are electrically coupled to the semiconductor die and/or contact fingers in the second package. Thus, once soldered together, packages 160a and 160b may function as a single electronic component 176, such as for example a single flash memory device. In this regard, it is understood that the types of semiconductor die in the respective packages 160a and 160b may vary in alternative embodiments.

For example, in one embodiment, package 160a may include one or more flash memory chips, and a controller such as an ASIC for communicating with a host device via contact fingers 114. Package 160b coupled thereto in this example may include only flash memory chips. Such a configuration would offer enhanced memory capabilities as compared to the package 160a by itself. In another configuration, package 160a may include one or more controllers and flash memory chips, and package 160b may include one or more controllers and flash memory chips. In a further embodiment, one of the packages 160a or 160b may include one or more controllers, and the other package 160b or 160a may include one or more flash memory chips.

It will be evident that the semiconductor packages which are coupled together need not originate from the same substrate panel. Thus, a first substrate panel may include all identical semiconductor packages, such as for example having a controller and one or more flash memory chips. And a second substrate panel may include all identical semiconductor packages, such as for example having only flash memory chips. Packages from these respective panels may then be coupled by solder paste 174 or solder balls as described above.

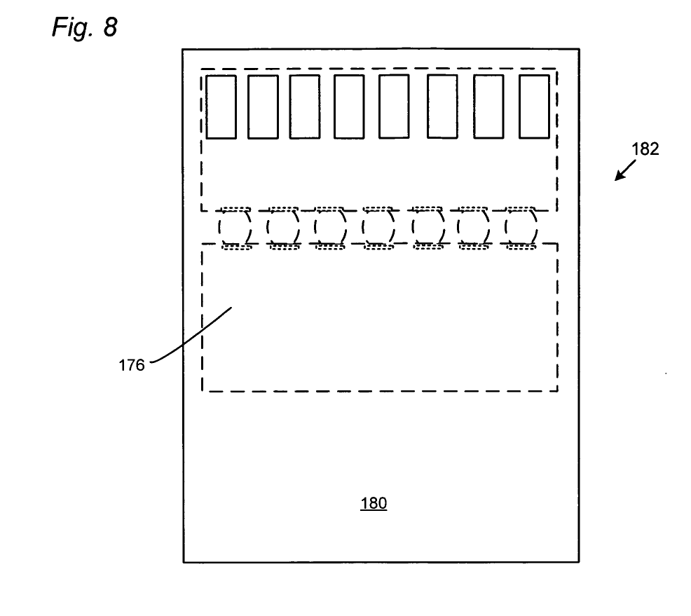

FIG. 8 illustrates the electronic component 176 enclosed within a lid 180 to form an electronic device 182 which may for example be a flash memory device. It is understood that such a flash memory device may be according to any of various known standard formats including a Secure Digital (SD) card, a Compact Flash, a Smart Media, a Mini SD Card, an MMC, an xD Card, a Transflash memory card or a Memory Stick. Other devices are contemplated.

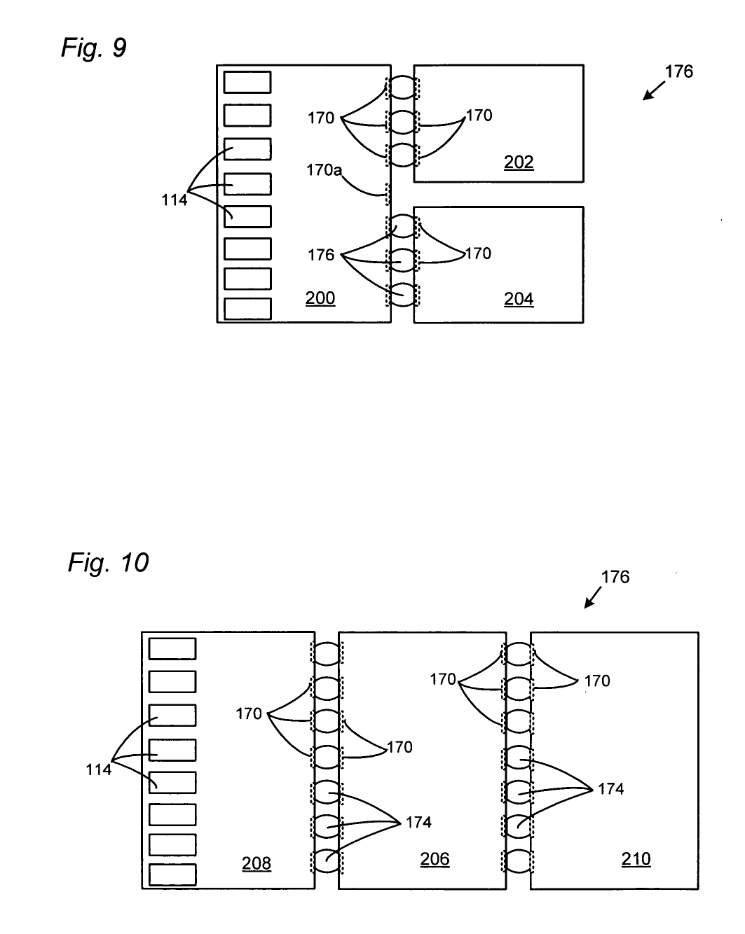

The electronic component 176 has been described thus far as two side-by-side soldered packages of at least approximately the same size and configuration. It is understood that other arrangements are contemplated. For example, as shown in FIG. 9, an electronic component 176 may include a first semiconductor package 200 soldered to two smaller semiconductor packages 202 and 204 via SMT pads 170 so as to operate as described above. In such an embodiment, one or more of the SMT pads 170 in one or more of the semiconductor packages may remain unconnected, such as for example SMT pad 170a in FIG. 9. Alternatively, if unused, SMT pad 170a (or other such unused pad) may be omitted when forming the substrate panel 100.

In a further embodiment shown in FIG. 10, one or more of the semiconductor packages in an electronic component 176 may include SMT pads at two opposed edges of the package. FIG. 10 illustrates a first semiconductor package 206 having SMT pads 170 at opposed edges so as to couple to a second semiconductor package 208 at one edge, and a third semiconductor package 210 at the opposite edge. It is understood that more than three such semiconductor packages may be coupled together in this manner.

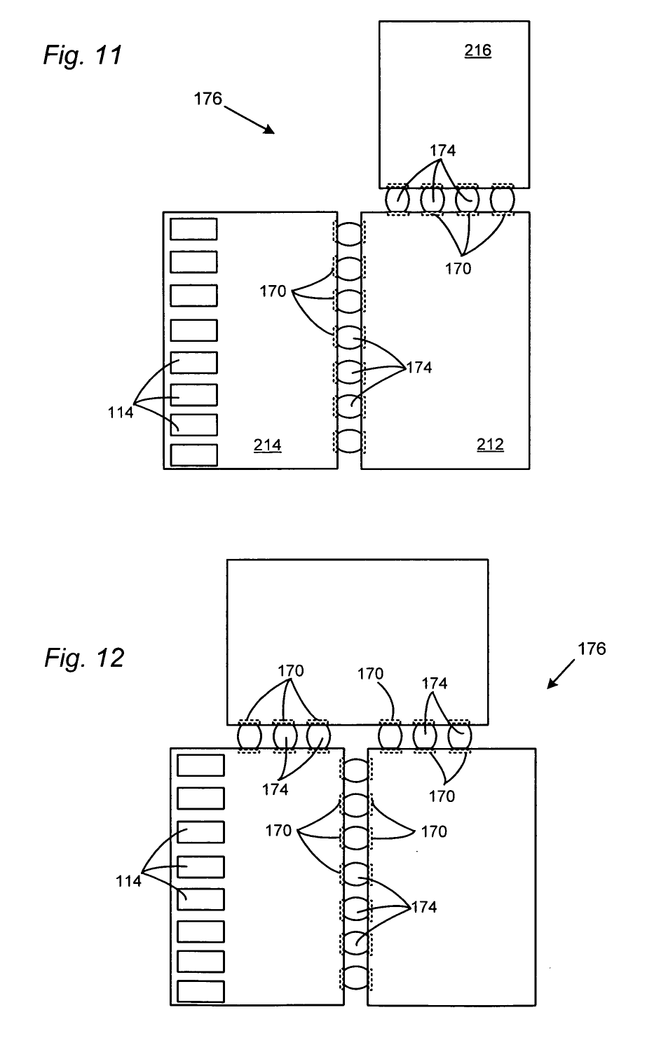

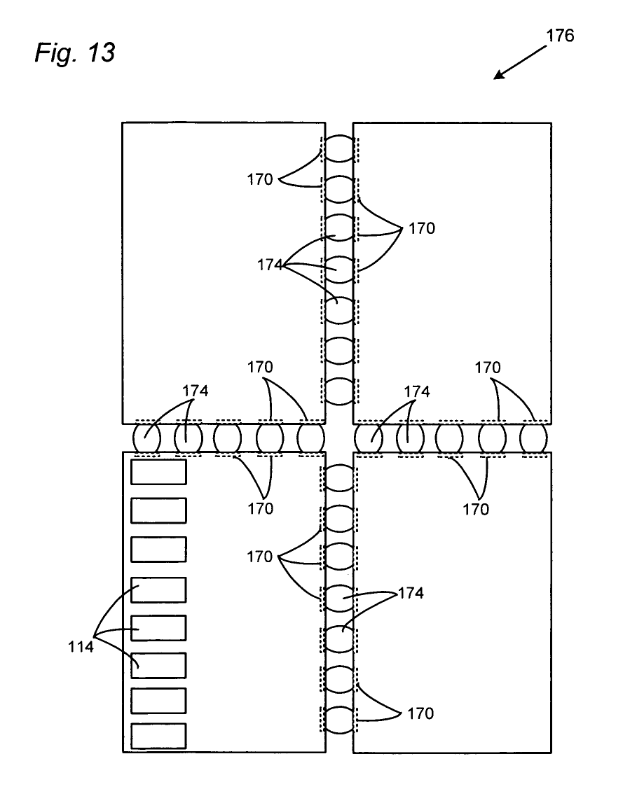

In a further embodiment shown in FIG. 11, one or more of the semiconductor packages in an electronic component 176 may include SMT pads at two adjacent edges of the package. FIG. 11 illustrates a first semiconductor package 212 having SMT pads 170 at adjacent edges so as to couple to a second semiconductor package 214 at one edge, and a third semiconductor package 216 at the adjacent edge. It is understood that more than three such semiconductor packages may be coupled together in this manner. It is also understood that the embodiment of FIGS. 10 and 11 may be combined to provide a plurality of packages in a plurality of configurations. Two such further configurations are illustrated in FIGS. 12 and 13. Others are contemplated.

Any of the above-described embodiments may be encased within a lid as described above and function as an electronic device such as a flash memory device.

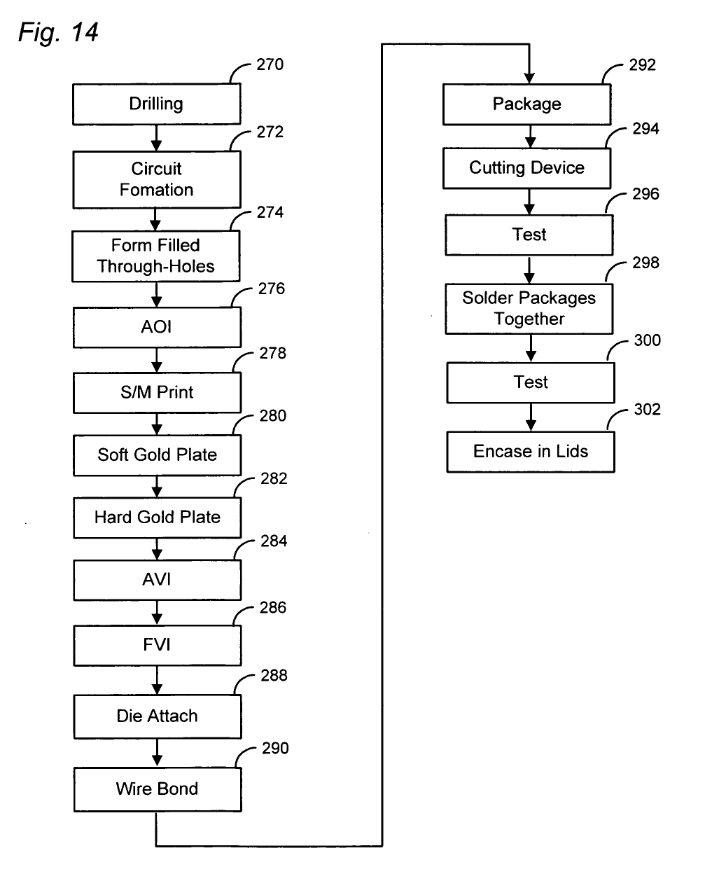

The flowchart of FIG. 14 sets forth an overall process for forming a finished electronic component 176 from a starting point of a substrate panel. In a step 270, the panel is drilled to define the filled through-holes 120 defining the SMT pads 170. The panel is also drilled in step 270 to provide reference holes off of which the positions of the respective substrates 100a, 100b are defined. The conductance pattern is then formed on the respective surfaces of the panel in step 272 as explained above, and the filled through-holes 120 are formed in a step 274. The panel may then be inspected in an automatic optical inspection (AOI) in step 276. Once inspected, the solder mask is applied to the panel in step 278.

After the solder mask is applied, the contact fingers may be plated. A soft gold layer is applied over certain exposed surfaces of the conductive layer on the bottom surface of the substrate panel, as for example by thin film deposition, in step 280. As the contact fingers are subject to wear by contact with external electrical connections, a hard layer of gold may be applied, as for example by electroplating, in step 282. It is understood that a single layer of gold may be applied in alternative embodiments.

The individual substrate panels may then be inspected and tested in an automated inspection process (step 284) and in a final visual inspection (step 286) to check electrical operation, and for contamination, scratches and discoloration. The substrate panels that pass inspection are then sent through the die attach process in step 288. The wire bonds and other electrical connections are then made on the substrate panel in a step 290, and the substrate panel and die are then packaged in step 292 in a known transfer molding process to form a JEDEC standard (or other) packages as described above.

A cutting device then separates the panel into individual packages 160 in step 294. The individual packages may undergo further electrical and burn in testing in step 296. Those that pass this inspection may be soldered together side-by-side as described above in step 298. The finished electronic component 176 may again be tested in step 300. Where the electronic component forms a flash memory device within lids 180, the packages may be enclosed within lids 180 in a step 302. It is understood that an electronic component 176 may be formed by other processes in alternative embodiments.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A substrate panel for a plurality of semiconductor packages, the substrate panel including:
a first area for a first semiconductor package;
a second area for a second semiconductor package;
a boundary between the first and second areas along which the first and second semiconductor packages are singulated; and
an electrically conductive material within a through-hole through the substrate and along the boundary between the first and second areas, the through-hole residing partially within the first area and partially within the second area, the electrically conductive material having a first conductive portion capable of being exposed in an edge of the first semiconductor package upon singulation from the substrate panel.

2. A substrate panel as recited in claim 1, the electrically conductive material further having a second conductive portion capable of being exposed in an edge of second semiconductor package upon singulation from the substrate panel.

3. A substrate panel as recited in claim 1, wherein the electrically conductive material includes at copper.

4. A substrate panel as recited in claim 1, wherein the electrically conductive material includes at gold.

5. An electronic component, comprising:
a first semiconductor package including a first semiconductor die;
a second semiconductor package including a second semiconductor die; and
an electrically conductive material for electrically and structurally coupling the first semiconductor package to the second semiconductor package at least one point between the first and second semiconductor packages, the first semiconductor die capable of communication with the second semiconductor die via the electrically conductive material.

6. An electronic component as recited in claim 5, further comprising a first conductive pad on the first semiconductor package, and a second conductive pad on the second semiconductor package, the electrically conductive material coupling the first semiconductor package to the second semiconductor package at the first and second conductive pads.

7. An electronic component as recited in claim 5, wherein the first and second semiconductor packages are coupled side-by-side to each other.

8. An electronic component as recited in claim 5, wherein the electrically conductive material is solder paste.

9. An electronic component as recited in claim 5, wherein the electrically conductive material is at least one solder ball.

10. An electronic component as recited in claim 5, further comprising at least a third semiconductor package including at least a third semiconductor die, the electrically conductive material further capable of electrically and structurally coupling the third semiconductor package to at least one of the first and second semiconductor packages at at least one point between the first and at least one of the first and second semiconductor packages, the third semiconductor die capable of communication with at least one of the first and second semiconductor die via the electrically conductive material.

11. An electronic component as recited in claim 10, wherein the first, second and at least third semiconductor packages are coupled side-by-side to each other.

12. An electronic component, comprising:
a first semiconductor package including a first semiconductor die on a first substrate, the first substrate including a first contact pad formed at an edge of the first semiconductor package;
a second semiconductor package including a second semiconductor die on a second substrate, the second substrate including a second contact pad formed at an edge of the second semiconductor package; and
electrically conductive material for coupling the first contact pad to the second contact pad, the first semiconductor die capable of communication with the second semiconductor die via the first and second contact pads and the electrically conductive material.

13. An electronic component as recited in claim 12, wherein the first and second contact pads are formed in a through-hole through the substrate panel.

14. An electronic component as recited in claim 12, wherein the first package is singulated from a substrate panel along a cut line, the substrate panel including a through-hole at least partially filled with a metal, the through-hole being cut during singulation of the first semiconductor package from the substrate panel, the metal in the cut through-hole forming the first contact pad.

15. An electronic component as recited in claim 12, wherein the first semiconductor package includes a controller chip and one or more flash memory chips and the second semiconductor package includes one or more flash memory chips.

16. An electronic component as recited in claim 15, wherein the first semiconductor package further includes contact fingers for communication between electronic component and a host device operable with the electronic component.

17. An electronic component as recited in claim 12, wherein the first semiconductor package includes a plurality of controller chips and the second semiconductor package includes one or more flash memory chips.

18. An electronic component as recited in claim 12, wherein the first semiconductor package includes a controller chip and one or more flash memory chips and the second semiconductor package includes a controller chip and one or more flash memory chips.

19. An electronic component as recited in claim 12, wherein the first and second semiconductor packages are coupled side-by-side to each other.

20. An electronic component as recited in claim 12, wherein the electrically conductive material is solder paste.

21. An electronic component as recited in claim 12, wherein the electrically conductive material is at least one solder ball.

22. An electronic component as recited in claim 12, further comprising at least a third semiconductor package including at least a third semiconductor die, the electrically conductive material further capable of electrically and structurally coupling the third semiconductor package to at least one of the first and second semiconductor packages at at least one point between the third semiconductor package and at least one of the first and second semiconductor packages, the third semiconductor die capable of communication with at least one of the first and second semiconductor die via the electrically conductive material.

23. An electronic component as recited in claim 22, wherein the first, second and at least third semiconductor packages are coupled side-by-side to each other.

24. An electronic device, comprising:
a first semiconductor package including a first semiconductor die on a first substrate, and a first contact pad formed in a through-hole at least partially in the first substrate;
a second semiconductor package including a second semiconductor die on a second substrate, and a second contact pad formed in a through-hole at least partially in the second substrate;
solder for electrically and structurally coupling the first contact pad to the second contact pad, the first semiconductor die capable of communication with the second semiconductor die via the first and second contact pads and the electrically conductive material; and
a lid for encasing the first semiconductor package, the second semiconductor package, and the electrically conductive material.

25. An electronic device as recited in claim 24, the lid conforming to a lid for one of a Secure Digital card, a Compact Flash, a Smart Media, a Mini SD Card, an MMC, an xD Card, a Transflash memory card or a Memory Stick

26. An electronic device as recited in claim 24, wherein the first semiconductor package includes a controller chip and one or more flash memory chips and the second semiconductor package includes one or more flash memory chips.

27. An electronic device as recited in claim 24, wherein the first semiconductor package includes a plurality of controller chips and the second semiconductor package includes one or more flash memory chips.

28. An electronic device as recited in claim 24, wherein the first semiconductor package includes a controller chip and one or more flash memory chips and the second semiconductor package includes a controller chip and one or more flash memory chips.

29. An electronic device as recited in claim 24, wherein the first and second semiconductor packages are coupled side-by-side to each other.

30. An electronic device as recited in claim 24, further comprising at least a third semiconductor package including at least a third semiconductor die, the solder further capable of electrically and structurally coupling the third semiconductor package to at least one of the first and second semiconductor packages at least one point between the third semiconductor package and at least one of the first and second semiconductor packages, the third semiconductor die capable of communication with at least one of the first and second semiconductor die via the electrically conductive material.

31. An electronic device as recited in claim 30, wherein the first, second and at least third semiconductor packages are coupled side-by-side to each other.

32. A method of forming a semiconductor device including a plurality of semiconductor packages, comprising the steps of:
(a) forming a through-hole in a substrate panel for a first semiconductor package of the plurality of semiconductor packages;
(b) at least partially filling the through-hole formed in said step (a) with a conductive material;
(c) singulating the semiconductor package along a line running through the filled through-hole to leave a portion of the conductive material of the through-hole exposed at an edge of the semiconductor package; and
(d) soldering the semiconductor package at the portion of exposed conductive material to a second semiconductor package.

33. A method of forming a semiconductor device as recited in claim 32, the second semiconductor package formed by the steps of:
(e) forming a through-hole in a substrate panel for the second semiconductor package;
(f) at least partially filling the through-hole formed in said step (e) with a conductive material;
(g) singulating the second semiconductor package along a line running through the filled through-hole to leave a portion of the conductive material of the through-hole exposed at an edge of the second semiconductor package; and
(h) soldering the second semiconductor package at the portion of exposed conductive material to the first semiconductor package.

34. A method of forming a semiconductor device as recited in claim 32, further comprising the step of enclosing the first and second soldered semiconductor packages in a lid.
